(19) United States
(12) Patent Application Publication
(10) Pub. No.: US 2016/0370420 A1
(43) Pub. Date: Dec. 22, 2016

(54) APPARATUS AND METHOD FOR SPARK FAULT DETECTION AND TYPING

(71) Applicants: Richard J. Langley, Old Lyme, CT (US); Thomas L. Listorti, Old Saybrook, CT (US)

(72) Inventors: Richard J. Langley, Old Lyme, CT (US); Thomas L. Listorti, Old Saybrook, CT (US)

(73) Assignee: CLINTON INSTRUMENT COMPANY, Clinton, CT (US)

(21) Appl. No.: 14/740,844

(22) Filed: Jun. 16, 2015

(51) Int. Cl. G01R 31/12; G01R 31/02

(52) U.S. Cl. CPC G01R 31/1272; G01R 31/022; G01R 31/025

(57) ABSTRACT

A spark fault tester apparatus includes an electrode; a power supply operatively connected to provide an electrical field at the electrode; a voltage monitoring module operatively connected to measure the intensity of the electrical field at the electrode; a current monitoring module operatively connected to measure a current output of the power supply; and a microprocessor operatively connected to sample the voltage monitoring module and the current monitoring module, and to adjust the power supply. The microprocessor implements a voltage regulation algorithm and a fault typing algorithm, based on samples of the voltage and current monitoring modules, to distinguish among at least two types of insulation defects.

### BACKGROUND

Technical Field

The invention relates to testing apparatus and methods for quality assurance based on electrical resistance. Particular embodiments relate to apparatus and methods for quality assurance of electrical cable insulation.

Discussion of Art

A key purpose for insulating an electrical cable is mitigate hazards of electrical shock or ignition that an energized cable presents to nearby personnel and structures. Another purpose of cable insulation is to avert abrasive damage to the cable. Instead, the insulation will be abraded.

Sometimes, abrasions or imperfections in coating processes can damage the insulation on a cable. Beyond compromising the ability of the insulation to protect the cable, even minor defects (pinholes or thinned spots) can render the insulation ineffectual to protect personnel and structures from electrical current carried by the cable when energized. Larger defects (bare metal or gross bare wire conditions) can present severe risks of electrocution or combustion.

Accordingly, cable manufacturers presently use various modes of cable insulation inspection. One mode of inspection, which has been approved by the Underwriters Laboratories, is known as “spark testing.” In spark testing, an insulated cable is run lengthwise through an electrode that is charged by a power supply to a relatively high voltage (on the order of a few thousand volts DC, AC or Impulse). At least one end of the insulated cable is grounded. Voltage at the electrode is monitored by supporting test circuitry. In case the electrode voltage dips below its controlled value, this dip is interpreted to indicate an insulation defect that is permitting the electrode voltage to at least partially discharge through the insulation and cable to ground. In order to avert overcurrent damage to the power supply, conventional test circuitry may respond to a voltage dip by shutting off the power supply. Because the cable is being continuously run lengthwise through the electrode, the power supply can be restored following a fault clearing delay or dwell time. Additionally, the voltage dip can be correlated to a location along the cable by rote calculations.

In case an insulation fault is detected, it may be random and unique, or may recur in sporadic or periodic nature. In case of sporadic or periodic faults, it will be desirable to troubleshoot the cable manufacturing process and equipment, in order to identify and correct the root cause of recurring faults. Presently, under conventional operation of spark fault test circuitry, the only datum available for troubleshooting is the distance between recurring faults. Troubleshooting a faulty manufacturing process could be improved by obtaining additional data from the spark fault tester, e.g. by a new and different mode of operation of the test circuitry.

### SUMMARY OF INVENTION

According to embodiments of the invention, a spark fault tester apparatus includes an electrode; a power supply operatively connected to provide an electrical field at the electrode; a voltage monitoring module operatively connected to measure the intensity of the electrical field at the electrode; a current monitoring module operatively connected to measure a current output of the power supply; and a microprocessor operatively connected to sample the voltage monitoring module and the current monitoring module, and to adjust the power supply. The microprocessor implements a voltage regulation algorithm and a fault typing algorithm, based on samples of the voltage and current monitoring modules, to distinguish among at least two types of insulation defects.

Embodiment of the invention implement a method for typing insulation faults on moving wire, which includes moving the wire through an electrode; applying an electrical field from a power supply module to the electrode; detecting an insulation fault; and continuing to apply the electrical field to the electrode even after the insulation fault is detected.

Varied exemplary embodiments of the invention, as briefly described above, are illustrated by certain of the following figures.

### BRIEF DESCRIPTION OF DRAWINGS

FIG. 1 depicts schematically a high voltage spark test apparatus in which aspects of the invention can be implemented.

FIGS. 2A-2C depict schematically a process flow for insulation fault detection and typing, according to an embodiment of the invention.

FIGS. 3A-3C depict schematically a process flow for voltage regulation during normal operation and in the presence of an insulation fault, according to an embodiment of the invention.

FIG. 4 depicts a spark fault trace for a short interval of bare wire (metal contact), as diagnosed according to an embodiment of the invention.

FIG. 5 depicts a spark fault trace for a plurality of insulation pinholes, as diagnosed according to an embodiment of the invention.

FIG. 6 depicts a spark fault trace for an insulation pinhole, as diagnosed according to an embodiment of the invention.

FIG. 7 depicts a spark fault trace for a prolonged metal contact (“gross bare wire”), as diagnosed according to an embodiment of the invention.

### DETAILED DESCRIPTION

Embodiments of the invention are described specifically with reference to a high voltage high frequency AC spark test apparatus, making use of a particular type of electrode. However, the invention could equally be implemented in a DC, AC, or Impulse spark tester, or using other types of electrodes or a lower range of electrode voltage, as further explained below. Embodiments of the invention could be applied not only in testing cable insulation, but also for quality assurance regarding mechanical defects (e.g., cracks, holes, or thinned portions) of sheets, films, or tubes.

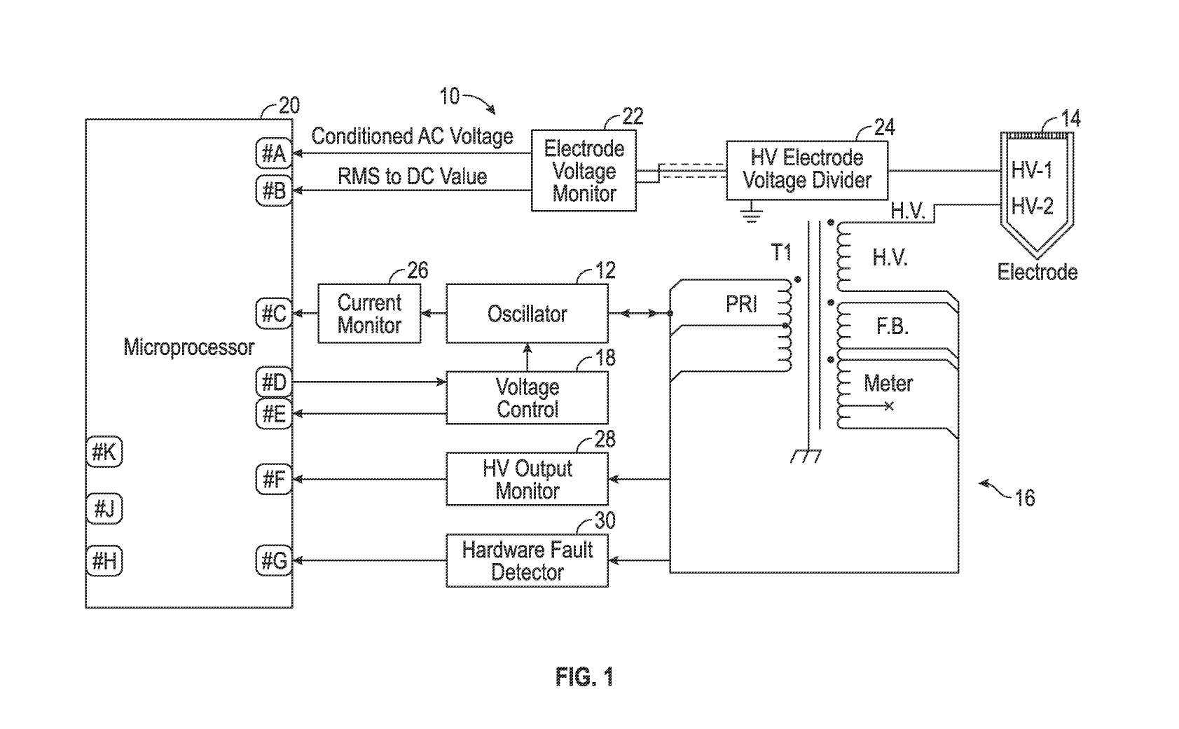

FIG. 1 depicts schematically a high voltage spark test apparatus 10, in which aspects of the invention can be implemented. The exemplary spark test apparatus 10 includes an oscillator 12, which drives a high voltage electrode 14 via a step-up transformer 16. In certain embodiments the high voltage electrode 14 is a filament type electrode that is configured to provide for continuous contact of the filaments against a test product (wire) that is fed through the electrode. For example the electrode 14 may be of a type as disclosed and claimed in co-pending and commonly owned application [Attorney Docket No. 0319-0053] “Improved Spark Tester Apparatus and Method”. In other embodiments the electrode 14 may be a brush or water bath electrode.

The oscillator 12 is driven by a voltage control module 18, which in turn is adjusted by operation of a microprocessor 20. The oscillator 12, the step-up transformer 16, and the voltage control module 18 collectively constitute a high voltage high frequency power supply 19. Alternatively, the spark test apparatus 10 may deliver DC voltage to the electrode 14, i.e., the power supply 19 may consist of a voltage control module, without any oscillator or step-up transformer.

In normal operation, the microprocessor adjusts the voltage control module 18 in response to inputs from an electrode voltage monitor module 22 (which measures the intensity of the electrical field at the electrode 14), an oscillator current monitor module 26 (which measures the amplitude of current output from the oscillator 12), and a transformer high voltage winding output monitor module 28 (which measures the intensity of the electrical field provided from the step-up transformer 16 to the electrode 14). Additionally, during normal operation the microprocessor 20 monitors these same inputs for the purpose of detecting insulation defects or faults that may be present on a wire moving through or past the electrode 14. The microprocessor 20 also monitors a hardware fault detector 30, which is operatively connected with the step-up transformer 16 for the purpose of detecting an arc condition (i.e. high-current spark discharge to ground) within the electrode 14. The electrode voltage monitor module 22 is operatively connected with the electrode 14 via a high voltage electrode voltage divider 24, which can be implemented by resistors or by capacitors.

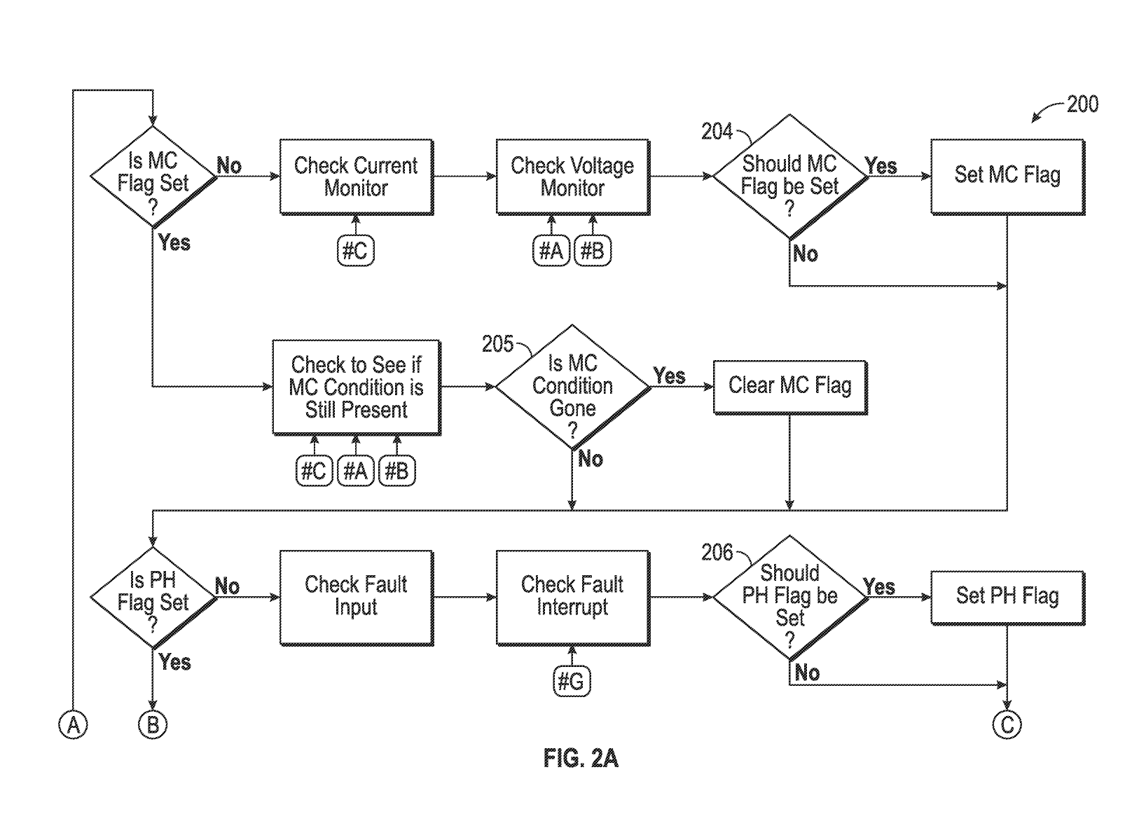

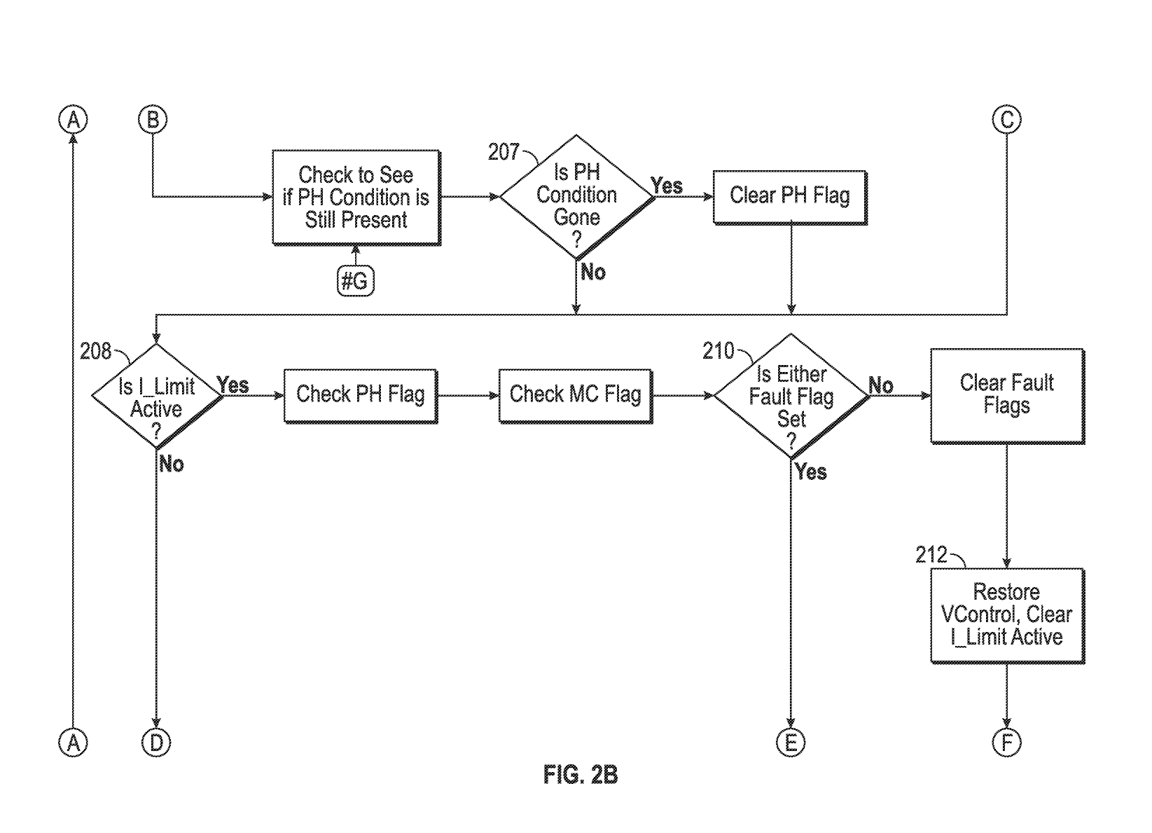

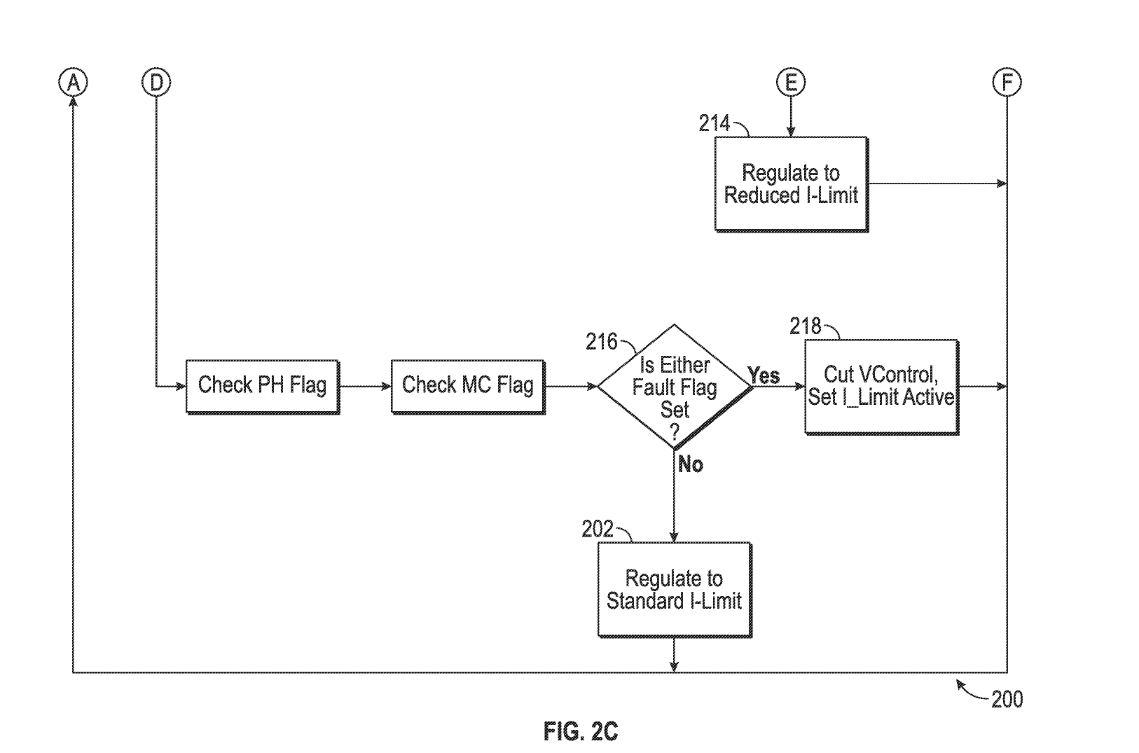

As mentioned, the microprocessor 20 adjusts the voltage control module 18 responsive to electrode voltage, oscillator current, and transformer high voltage winding output, generally according to a voltage regulation algorithm 200 as shown in FIG. 2. The microprocessor 20 also accounts for feedback direct from the voltage control module 18.

In normal operation, the microprocessor 20 adjusts the voltage control module 18 to maintain 202 electrode voltage amplitude at a value set by an operator, e.g., about 15 kV. However, any voltage selected from a range from about 500 V to about 20 kV may be efficacious depending on the size and insulation thickness of a cable or wire to be assessed using the spark test apparatus 10. The oscillator 12 varies the electrode voltage (typically in a sine wave) at a nominal frequency of about 3000 Hz. However, any frequency selected from a range of about 1000 Hz to about 5000 Hz may be efficacious. Based on the input received from the oscillator current monitor module 26, the microprocessor also adjusts the voltage control module 18 to maintain under a normal operating limit of significantly less than 1 A (e.g., less than about 400 mA, or even less than about 4 mA). These adjustments during normal operation can be accomplished by the microprocessor 20 implementing conventional voltage control and current limit algorithms while monitoring its input ports #A, #B, #C, #E, #F, and #G. The microprocessor sends adjustment signals to the voltage control 18 via output port #D.

Thus, the spark test apparatus 10 under normal conditions, testing insulated wire, will be set to a specified test voltage. This test voltage can be specified by a wire and cable specification or an in house quality program. The test voltage is set on the spark tester using front panel controls, or other optional communication protocols that can be configured into the spark tester.

Once the spark test apparatus 10 has the required test voltage set it will implement the voltage control algorithm 200 to adjust its high voltage output to that value. Specifically, under normal operating conditions the spark test apparatus 10 will regulate 202 the test voltage to the set value regardless of the load condition that it is put on by the wire or product under test. This regulation essentially is done in a loop, in which the spark test apparatus 10 monitors both the actual high voltage output (#A) at the electrode 14 as well as the output (#F) of the high voltage power transformer 16. The output current (#C) of the oscillator 12 (i.e. the current required to generate the set voltage) is also monitored. Depending on the load that the product under test may place on the spark test apparatus 10, the current required to produce the required set voltage will vary. Additionally, the voltage regulation algorithm 200 monitors the hardware fault detector module 30 output signal #G.

In order to provide some hysteresis in the voltage regulation algorithm 200, the spark test apparatus 10 may sample the input ports at a relatively low rate (i.e. at sample rate not exceeding the oscillator frequency), and will constantly make adjustments 202 to make sure that the electrode output voltage is at the required set point. In case the monitored values #A, #F, #C, or #G suggest that an insulation fault has occurred, then the microprocessor 20 will set a fault flag.

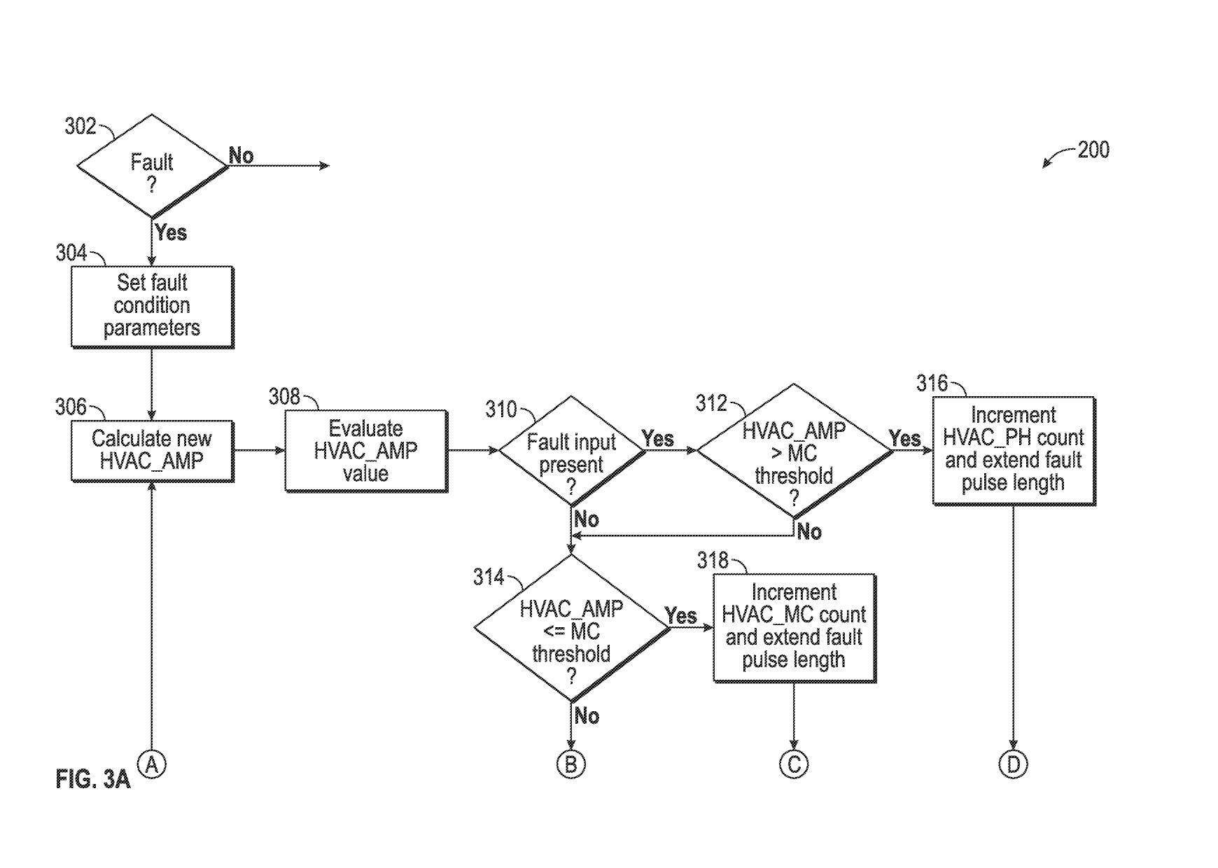

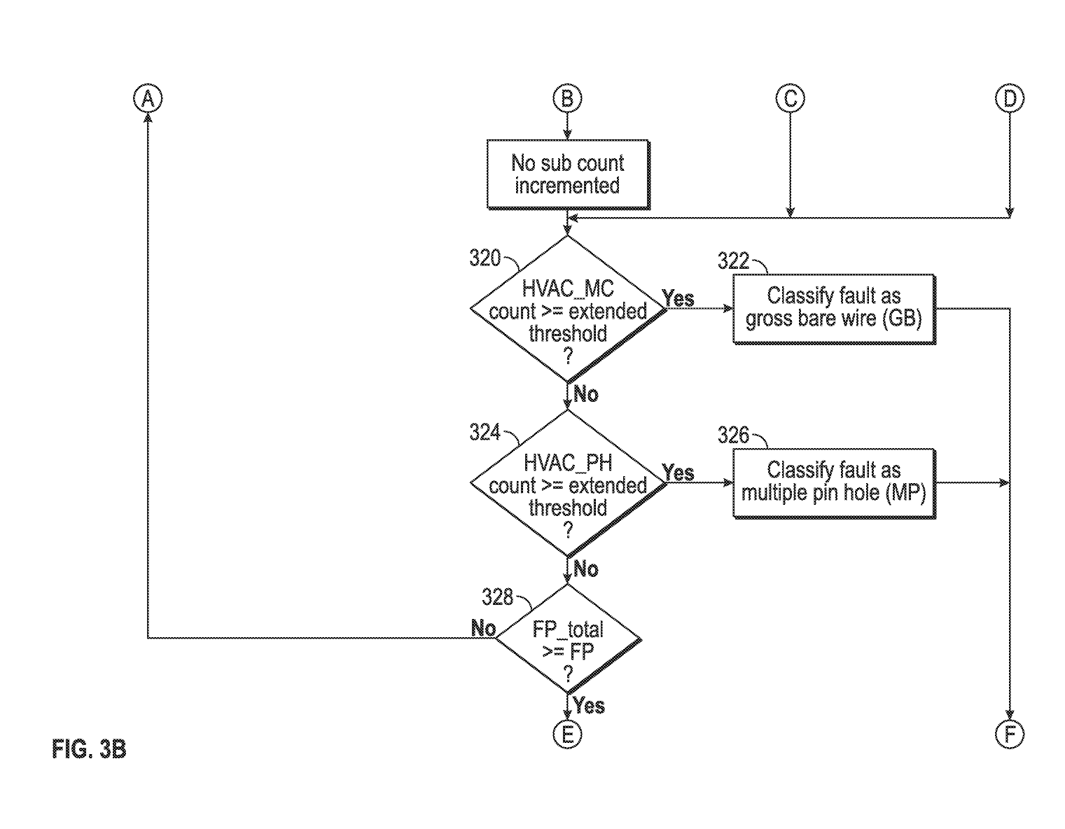

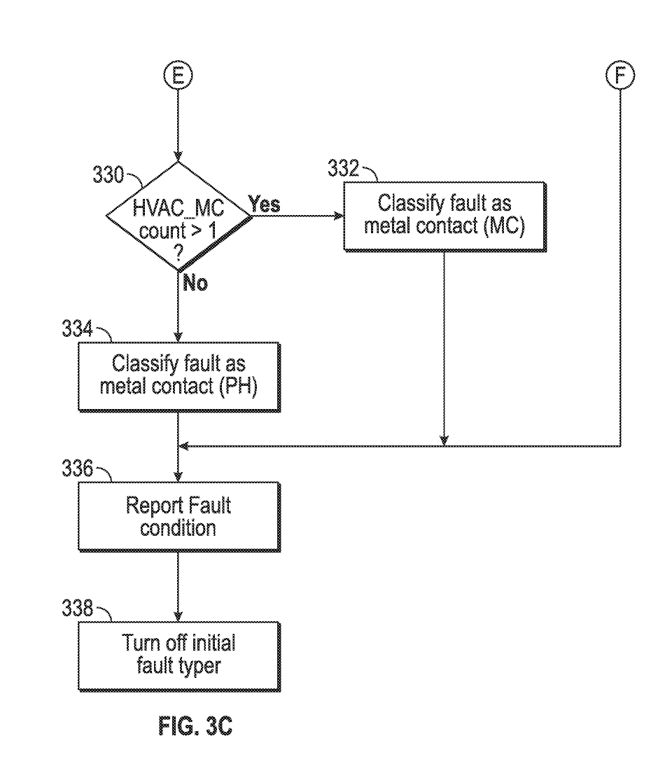

For example, a first way of detecting a fault condition, within the voltage regulation algorithm 200 firmware that is implemented in the microprocessor 20 during normal operating conditions, is by the microprocessor 20 comparing oscillator output current (port #C) to a current high threshold while also comparing the electrode output voltage (port #A or #B) or the step-up transformer high voltage winding voltage (port #F) to a voltage low threshold. Notably, the oscillator output current is measured as a very close proxy for the output current of the high-voltage transformer 16, which is the output of the power supply 19 as a whole. In case the oscillator output current is high and either of the voltages is low, this condition will generate a voltage-current mismatch signal that can trigger 204 the voltage regulation fault logic to set a “metal contact” fault flag MC. This fault flag MC is distinct from a “metal contact” flag HVAC_MC that is set by a fault typer algorithm 300, based on slower samples, as discussed below with reference to FIG. 3.

Another way of detecting a fault condition is by the hardware fault detection module 30, which detects an actual arc condition at the electrode 14 based on signals from the high voltage power supply 16 and from the oscillator 12. The hardware fault detection module 30 then provides an arc condition signal to the microprocessor 20 input port #G. Receipt of the arc condition signal #G will trigger 206 the microprocessor 20 to set a “pinhole” fault flag PH. This fault flag PH is distinct from a “pinhole” flag HVAC_PH that is set by the fault typer algorithm 300, as further discussed below.

In response 216 to either fault flag MC or PH being set, then the microprocessor 20 will cut 218 voltage control, and will set 218 a current-limited mode 208 in which, so long as either fault flag remains 210 set, the power supply 19 is adjusted to maintain 214 a reduced (fault tolerant) current limit. The reduced current limit may be selected based on circuit parameters, e.g., expected reactance from the oscillator 12 through the high-voltage transformer 18 and the electrode 14 to ground. While the current-limited mode 208 remains active, the microprocessor 20 will continually loop to check whether the fault flags have cleared. In case both fault flags clear, then the microprocessor 20 will restore 212 voltage control 202.

Concurrent with the voltage regulation algorithm 200, the microprocessor 20 also implements a fault detection and typing algorithm 300, which is based on data received at the aforementioned input ports #A, #B, #C, #F and #G as well as #E. The fault typing algorithm 300 makes use of data acquired from these input ports at a relatively rapid sample rate, i.e. at least in excess of the oscillator frequency. The more rapid sample rate for fault typing permits enhanced accuracy in diagnosis of insulation fault types. Continuously, the microprocessor 20 implements an algorithm step of detecting 302 whether a cable insulation fault is present within the electrode 14. This assessment is driven by the voltage regulation algorithm triggers 204, 206, responsive to oscillator output current levels (port #C), actual electrode voltage levels (ports #A and #B), the high voltage transformer output voltage (port #F), and also the hardware fault detector module 30 (port #G). The assessment 302 is parallel to the voltage regulation algorithm triggers 204, 206.

Under the fault typer algorithm 300, the microprocessor 20 can detect 302 a metal contact fault condition based on oscillator output current #C and electrode voltage #A, #B not matching or can detect 302 a pinhole fault condition based on an arc condition signal #G from the hardware fault detector module 30.

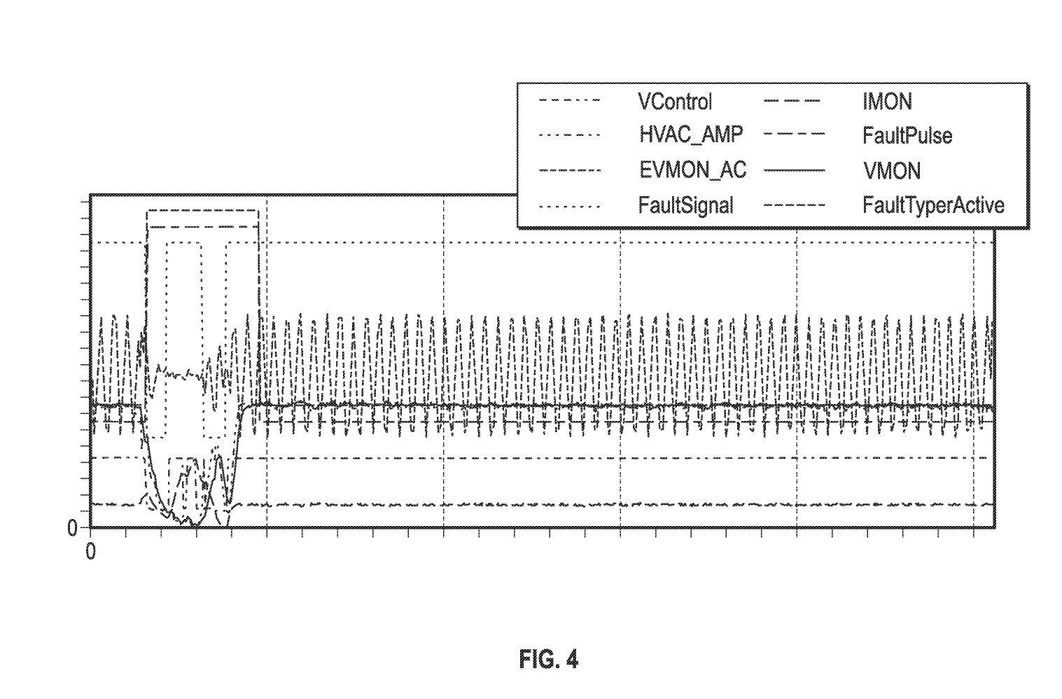

Under the fault logic that is activated in the case of detecting 302 a fault, the microprocessor 20 sets 304 at least the following parameters as the spark test apparatus 20 enters its fault mode. a. As discussed above with reference to the voltage regulation algorithm 200, the microprocessor 20 selects 208 a new subroutine 214 for adjusting the voltage control 18 to maintain output current of the oscillator 12 below a fault-tolerant limit of, e.g., no more than about 400 μA indicated at microprocessor input port #C. This fault-tolerant current limit prevents the insulation fault from creating excessive arc conditions within the electrode 14. Additionally, the microprocessor 20 b. sets a Fault Typer (FT) Active flag; c. sets a Fault Pulse (FP) Active flag; and d. calculates and sets an extended fault threshold value which is used for diagnosing extended fault conditions as further discussed below. The Fault Typer flag and Fault Pulse flag active periods can be seen in FIGS. 4-7, further discussed below.

While implementing the current limiting subroutine 214 of the voltage control algorithm 200, as shown in FIG. 2, the microprocessor 20 adjusts the voltage control module 18 to maintain oscillator output current #C at the fault-tolerant limit and monitors the step-up transformer output voltage #F as well as the electrode voltage #A. In case the electrode voltage ramps toward its normal value, without having the oscillator output current exceed a threshold value, then the microprocessor 20 clears the Fault Typer flag as well as the Fault Pulse Active flag. Otherwise, at least the Fault Pulse Active flag remains locked in. At least at the beginning of the current-limiting operation, the Fault Typer flag also remains locked in, as the fault logic (fault typer subroutine) 300 proceeds as explained below, in order to determine what is the fault condition.

Under the fault typer subroutine, the microprocessor 20 calculates 306 a value for HVAC_AMP, which is a pseudo-current value that is calculated based on minimum and maximum values of Electrode Voltage (EVMON_AC, as shown in FIGS. 4-7) that are obtained from the electrode voltage monitor module 22. HVAC_AMP is an estimate of a current that flows from the electrode 14 through an insulation fault to ground. HVAC_AMP is distinct from Imon (also shown in FIGS. 4-7), which is an actual (RMS) value of current output from the power supply 19 to the electrode 14. The microprocessor 20 evaluates 308 the HVAC_AMP value and the fault data. In particular, the hardware fault detector is re-checked 310 to see if an arc fault condition is present. In case the hardware fault detector module 30 provided an arc condition signal at port #G, then the HVAC_AMP value is checked 312 to see if it is greater than a pre-determined metal contact threshold value. On the other hand, in case the hardware fault detector module 30 did not provide an arc condition signal, then the HVAC_AMP value is checked 314 to see if it is less than the metal contact threshold value.

In case the HVAC_AMP value is greater than the metal contact threshold, and an arc condition signal is present at port #G, then the microprocessor 20 will increment 316 an HVAC_PH count. On the other hand, in case the HVAC_AMP is less or equal than the metal contact threshold, and an arc condition signal is not present at port #G, then the microprocessor 20 will increment 318 an HVAC_MC count. In case the HVAC_AMP value is mismatched to the signal from the hardware fault detector module 30, e.g., greater than metal contact threshold with no arc condition signal, then no count will be incremented.

Next the microprocessor 20 will check 320 whether the HVAC_MC count is greater than or equal to the extended fault threshold as set when entering the fault condition. If yes, the microprocessor will set 322 a Gross bare wire flag (GB) and will jump to a fault reporting step 336. If no, the microprocessor will proceed to check 324 whether the HVAC_PH count is greater than or equal to the extended fault threshold. If yes, the microprocessor will set 326 a Multiple pinhole flag (MP) and will jump to the fault reporting 336. Otherwise, the microprocessor will proceed to compare 328 a total fault pulse length (FP_total) (the actual duration of the fault condition until this time) against the (FP) Fault pulse value as set when entering the fault condition. This is to determine whether the test product (wire) has traveled to the end of the initial fault typer window. If not, the microprocessor will loop on evaluation of the fault. If yes, the microprocessor 20 will proceed to distinguish 330 fault type between metal contact and pin hole, based on the HVAC_MC value. In case the HVAC_MC count is greater than 1, a Metal contact flag (MC) will be set 332 and the microprocessor will jump to the fault reporting 336. On the other hand, in case the HVAC_MC count is 1 or less, then a pinhole flag (PH) will be set 334 and the microprocessor will continue to the fault reporting 336.

Fault reporting 336 can be implemented in various ways. For example, the various fault types GB, PH, MP, and/or MC may be reported as analog voltage levels that are provided at discrete output ports #H, #J, #K of the microprocessor 20. Alternatively, the various fault types may be encoded as digital signals, either for immediate display at an operating panel, or for transmission to a computer for further processing or storage. As one example of further processing, FIGS. 4-7 depict exemplary spark fault traces. Operation of the microprocessor 20, according to the algorithms 200, 300, will be further explained with reference to these traces.

After fault reporting 336, the microprocessor 20 will turn off the fault typer logic (clears the Fault Typer Active flag FT). However, the current-limited voltage regulation subroutine 214 will continue until the microprocessor 20 also is able to clear the MC or PH flags within the voltage regulation algorithm 200.

FIG. 4 depicts a spark fault trace for a short interval of bare wire (metal contact), as diagnosed according to an embodiment of the invention. At time step 402, monitored amplitude of power supply output voltage VMon (port #F, measurement taken across a metering winding of the high voltage transformer 16, as shown in FIGS. 4-7) drops while monitored amplitude of oscillator output current IMon (port #C) rises, establishing a current-voltage mismatch sufficient to trigger 204 the MC flag and to cause detection 302 of the bare wire insulation fault by the fault typer logic 300. This results in activation 216, 218, 208 of the current-limiting voltage regulation subroutine 214 and of the fault typer subroutine 300 within the microprocessor 20. As can be seen, while the test product (wire) continues to move through the electrode 14, the microprocessor 20 adjusts 214 the voltage control module 18 target voltage VControl (signal from microprocessor 20 to voltage control module 18, microprocessor port #D) toward its normal value each time that the current IMon drops below its fault tolerant limit. More particularly, the voltage regulation algorithm 200 clears 207 the metal contact fault flag MC whenever the current IMon drops below its fault tolerant limit. However, the fault typer algorithm 300 does not yet clear the HVAC_MC flag. This results in the voltage regulation algorithm 200 briefly returning 210, 212 to normal target level of VControl whereas the fault typer algorithm 300 continues to update 306 HVAC_AMP and to classify 334 the fault condition. In case the bare wire has not cleared from the electrode 14, then the normal level of VControl will cause IMon to exceed its normal limit, which will re-set 204 the metal contact fault flag MC. On the other hand, in case the bare wire has cleared from the electrode 14, then VControl will continue to rise toward its normal value while IMon remains below its limit. This combination of indications will leave 205 the metal contact fault flag MC clear. Following on from this, the microprocessor 20 also will clear Fault Pulse and Fault Typer Active flags and will return to normal regulation 202 of the voltage control module 18.

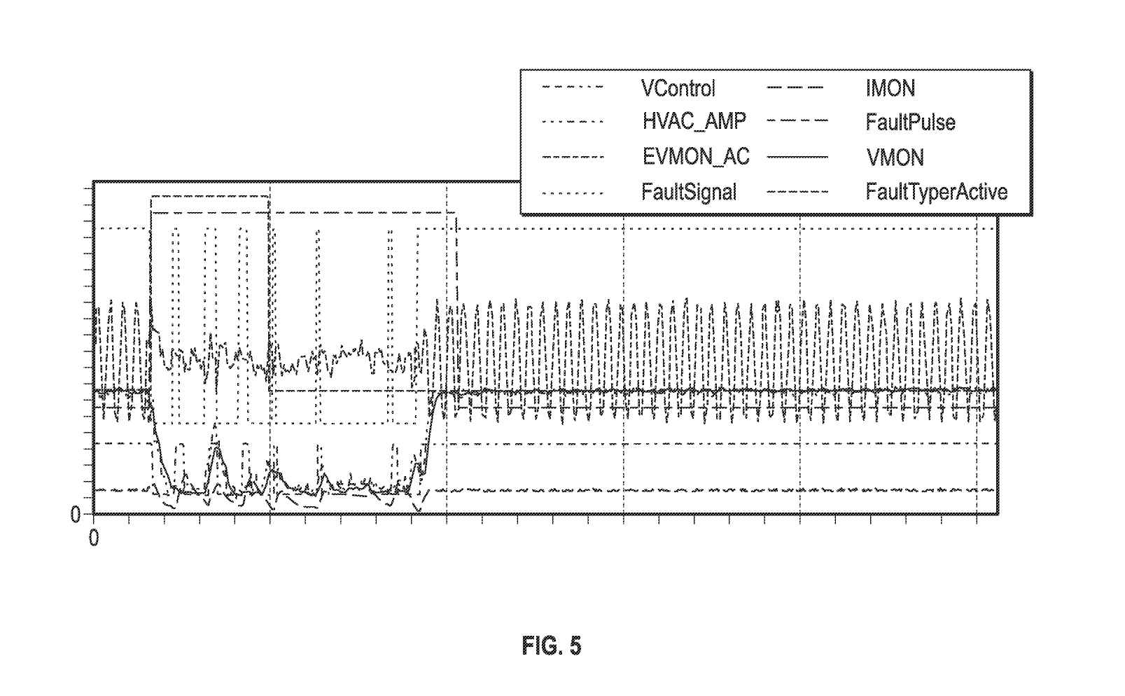

FIG. 5 depicts a spark fault trace for a plurality of insulation pinholes, as diagnosed according to an embodiment of the invention. Here, during the current-limited subroutine 214, VControl exhibits a prolonged sawtooth pattern due to each pinhole partly clearing the electrode before the next pinhole enters.

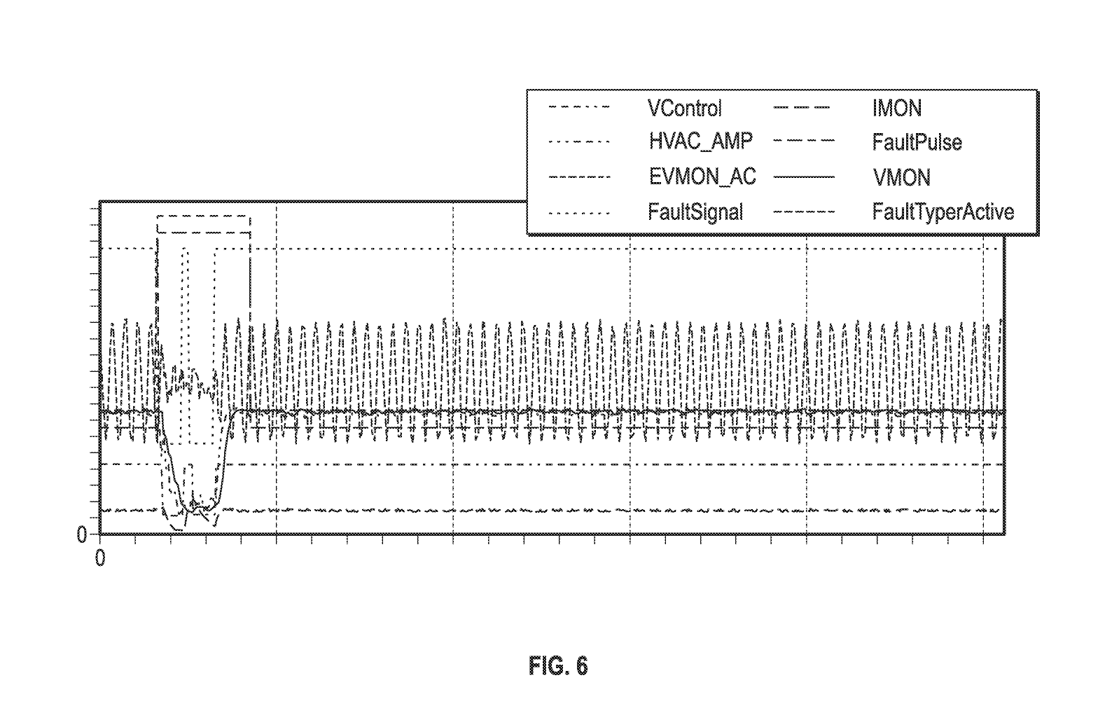

FIG. 6 depicts a spark fault trace for a single insulation pinhole, as diagnosed according to an embodiment of the invention. Here, VControl exhibits a single spike, followed by a return to normal level after the pinhole has cleared the electrode 14. The pinhole fault may have cleared the electrode at any time between the spike of VControl and the return to normal value; VControl returning to and remaining at normal value is predicated on IMon remaining below its normal limit, not directly on presence or absence of a fault within the electrode.

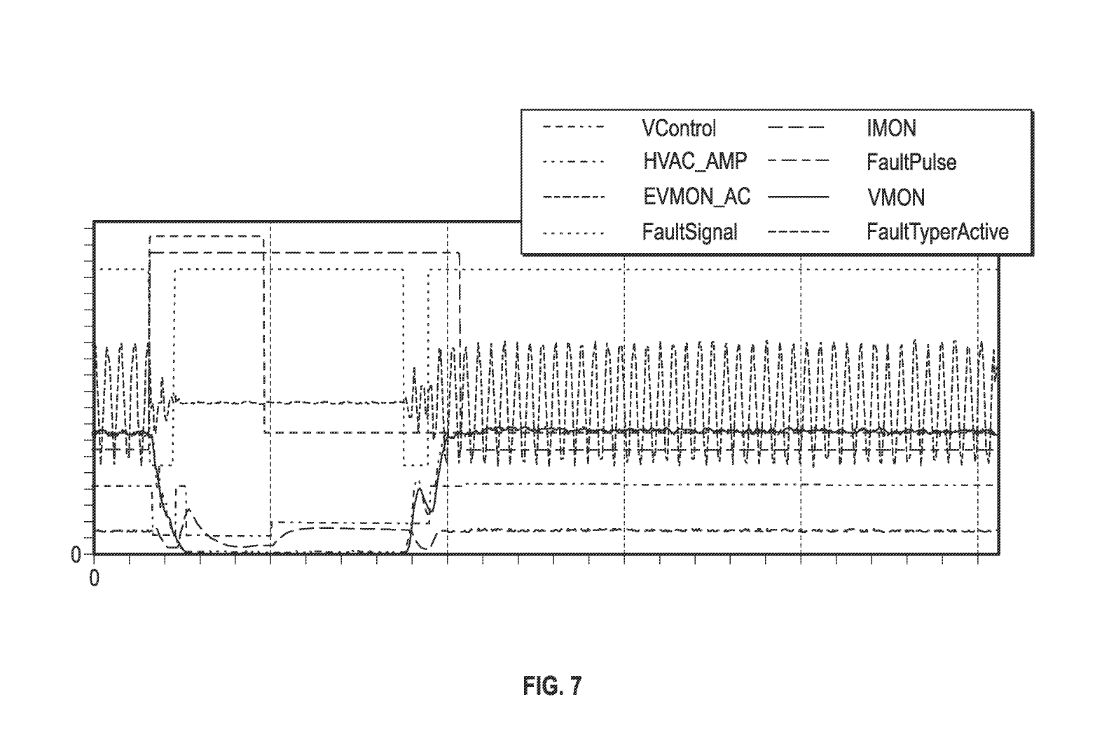

FIG. 7 depicts a spark fault trace for a prolonged metal contact (“gross bare wire”), as diagnosed according to an embodiment of the invention. Here, the Fault Typer flag FT clears out long before the bare wire has cleared the electrode 14. VMon remains near zero whereas IMon settles near its normal limit in response to a reduced target value of VControl. The microprocessor 20 restores VControl to its normal target only in response to IMon dropping off (below its fault tolerant limit) once the bare wire has cleared the electrode 14.

Thus, embodiments of the invention provide a spark fault tester apparatus that includes an electrode; a power supply operatively connected to provide an electrical field at the electrode; a voltage monitoring module operatively connected to measure the intensity of the electrical field at the electrode; a current monitoring module operatively connected to measure a current output of the power supply; and a microprocessor operatively connected to sample the voltage monitoring module and the current monitoring module, and to adjust the power supply. The microprocessor implements a voltage regulation algorithm and a fault typing algorithm, based on samples of the voltage and current monitoring modules, to distinguish among at least two types of insulation defects. The at least two types of insulation defects may include at least two of pinhole, multiple pinhole, metal contact, and gross bare wire. The microprocessor may implement a fault typing algorithm that includes steps of: receiving at the microprocessor at least one of an arc condition signal or a voltage-current mismatch signal; establishing a current limiting mode of voltage regulation; assessing, based at least on the intensity of the electrical field at the electrode and on presence or absence of an arc condition signal, whether a pinhole fault or a metal contact fault is present. The fault typing algorithm may further include steps of: incrementing a pinhole fault counter in case a pinhole fault is present; or incrementing a metal contact fault counter in case a metal contact fault is present; and indicating one of a pinhole fault, a multiple pinhole fault, a metal contact fault, or a gross bare wire fault, based on values of the pinhole fault counter and the metal contact fault counter. Assessing whether a pinhole fault or a metal contact fault is present may include calculating a current equivalent to minimum and maximum values of a voltage signal from the voltage monitoring module, comparing the calculated current to a threshold value, and detecting a pinhole fault in case the calculated current exceeds the threshold value and an arc condition signal is present, detecting a metal contact fault in case the calculated current is less than or equal the threshold value and no arc condition signal is present, or detecting no fault in other cases. The voltage regulation algorithm may include steps of: comparing a voltage signal from the voltage monitoring module to a current signal from the current monitoring module; monitoring for an arc condition signal from a hardware fault detector module; and adjusting power supply voltage to maintain the voltage signal at a normal target, in case no arc condition signal is detected and in case the current signal remains below a normal limit. The voltage regulation algorithm may also include a step of adjusting power supply voltage to maintain the current signal below a fault tolerant limit that is less than the normal limit, in case an arc condition signal is detected or in case the current signal exceeds the normal limit or in case the voltage signal and the current signal meet conditions to generate a voltage-current mismatch signal. The voltage regulation algorithm may include steps of: comparing a voltage signal from the voltage monitoring module to a current signal from the current monitoring module; monitoring for an arc condition signal from a hardware fault detector module; and adjusting power supply voltage to maintain the current signal below a fault tolerant limit that is less than the normal limit, in case an arc condition signal is detected or in case the voltage signal and the current signal meet conditions to generate a voltage-current mismatch signal. The power supply may include a voltage control module that is operatively connected through an oscillator to a step-up transformer, which has a high voltage winding that is operatively connected to supply the electrical field to the electrode. The apparatus may also include a hardware fault detector module that is operatively connected with the power supply to produce an arc condition signal based on real time measurements of the power supply.

Other embodiments of the invention implement a method for typing insulation faults on moving wire. The method includes moving the wire through an electrode; applying an electrical field from a power supply module to the electrode; detecting an insulation fault; and continuing to apply the electrical field to the electrode even after the insulation fault is detected. Applying the electrical field may include monitoring power supply output voltage and current, monitoring for an arc condition signal, and maintaining power supply output voltage at a normal target so long as power supply output current remains below a normal limit and no arc condition signal is detected. Continuing to apply the electrical field may include adjusting the intensity of the electrical field to maintain the power supply output current at a fault tolerant limit that is less than the normal limit. Continuing to apply the electrical field also may include adjusting the intensity of the electrical field to its normal target, in response to the power supply output current falling below its fault tolerant limit. Detecting an insulation fault may include calculating a current equivalent to minimum and maximum values of the monitored voltage; comparing the calculated current to a threshold value; and detecting a pinhole fault in case the calculated current exceeds the threshold value and an arc condition signal is present. Detecting an insulation fault also may include calculating a current equivalent to minimum and maximum values of the monitored voltage; comparing the calculated current to a threshold value; and detecting a metal contact fault in case the calculated current is less than or equal the threshold value and no arc condition signal is present. The method also may include counting detections of insulation faults while continuing to apply the electrical field, and diagnosing a type of insulation fault based on one or more counts of detections. Diagnosing a type of insulation fault may include diagnosing a multiple pinhole fault based on a value of a pinhole fault counter exceeding an extended fault threshold, and/or may include diagnosing a gross bare wire fault based on a value of a metal contact fault counter exceeding an extended fault threshold, or diagnosing a pinhole fault based on a value of a metal contact fault counter being zero and a value of a pinhole fault counter being less than an extended fault threshold.

Although exemplary embodiments of the invention have been described with reference to attached drawings, those skilled in the art nevertheless will apprehend variations in form or detail that are consistent with the scope of the invention as defined by the appended claims.

What is claimed is:

1. A spark fault tester apparatus comprising:
an electrode;
a power supply operatively connected to provide an electrical field at the electrode;
a voltage monitoring module operatively connected to measure the intensity of the electrical field at the electrode;
a current monitoring module operatively connected to measure a current output of the power supply; and
a microprocessor operatively connected to sample the voltage monitoring module and the current monitoring module, and to adjust the power supply;
wherein the microprocessor implements a voltage regulation algorithm and a fault typing algorithm, based on samples of the voltage and current monitoring modules, to distinguish among at least two types of insulation defects.

2. The apparatus of claim 1 wherein the at least two types of insulation defects include at least two of pinhole, multiple pinhole, metal contact, and gross bare wire.

3. The apparatus of claim 1 wherein the microprocessor implements a fault typing algorithm that includes steps of:
receiving at the microprocessor at least one of an arc condition signal or a voltage-current mismatch signal;
establishing a current limiting mode of voltage regulation;
assessing, based at least on the intensity of the electrical field at the electrode and on presence or absence of an arc condition signal, whether a pinhole fault or a metal contact fault is present.

4. The apparatus of claim 3 wherein the fault typing algorithm further includes steps of:
incrementing a pinhole fault counter in case a pinhole fault is present; or
incrementing a metal contact fault counter in case a metal contact fault is present; and
indicating one of a pinhole fault, a multiple pinhole fault, a metal contact fault, or a gross bare wire fault, based on values of the pinhole fault counter and the metal contact fault counter.

5. The apparatus of claim 3 wherein the step of assessing includes:
calculating a current equivalent to minimum and maximum values of a voltage signal from the voltage monitoring module,
comparing the calculated current to a threshold value, and
detecting a pinhole fault in case the calculated current exceeds the threshold value and an arc condition signal is present,
detecting a metal contact fault in case the calculated current is less than or equal the threshold value and no arc condition signal is present, or
detecting no fault in other cases.

6. The apparatus of claim 1 wherein the voltage regulation algorithm includes steps of:
comparing a voltage signal from the voltage monitoring module to a current signal from the current monitoring module;
monitoring for an arc condition signal from a hardware fault detector module; and
adjusting power supply voltage to maintain the voltage signal at a normal target, in case no arc condition signal is detected and in case the current signal remains below a normal limit.

7. The apparatus of claim 6 wherein the voltage regulation algorithm also includes a step of adjusting power supply voltage to maintain the current signal below a fault tolerant limit that is less than the normal limit, in case an arc condition signal is detected or in case the current signal exceeds the normal limit or in case the voltage signal and the current signal meet conditions to generate a voltage-current mismatch signal.

8. The apparatus of claim 1 wherein the voltage regulation algorithm includes steps of:
comparing a voltage signal from the voltage monitoring module to a current signal from the current monitoring module;
monitoring for an arc condition signal from a hardware fault detector module; and
adjusting power supply voltage to maintain the current signal below a fault tolerant limit that is less than the normal limit, in case an arc condition signal is detected or in case the voltage signal and the current signal meet conditions to generate a voltage-current mismatch signal.

9. The apparatus of claim 1 wherein the power supply includes a voltage control module that is operatively connected through an oscillator to a step-up transformer, which has a high voltage winding that is operatively connected to supply the electrical field to the electrode.

10. The apparatus of claim 9 further comprising a hardware fault detector module that is operatively connected with the power supply to produce an arc condition signal based on real time measurements of the power supply.

11. A method for typing insulation faults on moving wire, comprising:
moving the wire through an electrode;
applying an electrical field from a power supply module to the electrode;
detecting an insulation fault; and
diagnosing the insulation fault.

12. The method of claim 11 wherein diagnosing the insulation fault includes monitoring power supply output voltage and current, monitoring for an arc condition signal, and maintaining power supply output voltage at a normal target so long as power supply output current remains below a normal limit and no arc condition signal is detected.

13. The method of claim 11 wherein diagnosing the insulation fault includes adjusting the intensity of the electrical field to maintain the power supply output current at a fault tolerant limit that is less than the normal limit.

14. The method of claim 13 wherein diagnosing the insulation fault includes adjusting the intensity of the electrical field to its normal target, in response to the power supply output current falling below its fault tolerant limit.

15. The method of claim 11 wherein diagnosing the insulation fault includes:
calculating a current equivalent to minimum and maximum values of the monitored voltage;
comparing the calculated current to a threshold value; and
detecting a pinhole fault in case the calculated current exceeds the threshold value and an arc condition signal is present.

16. The method of claim 11 wherein diagnosing the insulation fault includes:
calculating a current equivalent to minimum and maximum values of the monitored voltage;
comparing the calculated current to a threshold value; and
detecting a metal contact fault in case the calculated current is less than or equal the threshold value and no arc condition signal is present.

17. The method of claim 11 wherein diagnosing the insulation fault includes counting detections of insulation faults while continuing to apply the electrical field, and diagnosing the insulation fault based on one or more counts of detections.

18. The method of claim 17 wherein diagnosing the insulation fault includes diagnosing a multiple pinhole fault based on a value of a pinhole fault counter exceeding an extended fault threshold.

19. The method of claim 17 wherein diagnosing the insulation fault includes diagnosing a gross bare wire fault based on a value of a metal contact fault counter exceeding an extended fault threshold.

20. The method of claim 17 wherein diagnosing the insulation fault includes diagnosing a pinhole fault based on a value of a metal contact fault counter being zero and a value of a pinhole fault counter being less than an extended fault threshold.
